(19) United States
(12) Patent Application Publication
(10) Pub. No.: US 2004/0256659 A1
(43) Pub. Date: Dec. 23, 2004

(54) MOS-gated transistor with improved UIS capability

(76) Inventors: Soo-seong Kim, Seoul (KR); Chong-man Yun, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/807,917

(22) Filed: Mar. 23, 2004

(30) Foreign Application Priority Data
Mar. 24, 2003 (KR) 03-18303

(51) Int. Cl. H01L 29/74

(52) U.S. Cl. 257/316

(57) ABSTRACT

In accordance with the present invention, a transistor includes a semiconductor substrate forming a collector region. A drift region of a first conductivity type extends over the semiconductor substrate. First and second well regions of a second conductivity each extends from an upper surface of the drift region into and terminates within the drift region. The first well region is coupled to an emitter terminal while the second well region floats. The first and second well regions are separated by an impurity region of the first conductivity type such that each of the first and second well regions forms a separate pn junction with the impurity region.

### CROSS-REFERENCES TO RELATED APPLICATIONS

This application claims priority to Korean Patent Application No. 2003-18303, filed on Mar. 24, 2003, in the Korean Intellectual Property Office, the disclosure of which is incorporated herein by reference in its entirety.

### BACKGROUND OF THE INVENTION

The present invention relates in general to a MOS-gated transistor used as a switching device, and more particularly to a MOS-gated transistor with improved unclamped inductive switching (UIS) capability.

MOS-gated power transistors such as power metal oxide semiconductor field effect transistors (MOSFETs) and power insulated gate bipolar transistors (IGBTs) require sufficient ruggedness. Here, ruggedness means endurance to an avalanche current. In particular, when a MOS-gated transistor is coupled to an inductive load, ruggedness is an important factor determining stability of a device. That is, when a MOS-gated transistor is coupled to an inductive load, UIS may occur such that a large amount of current suddenly flows through the MOS-gated transistor, resulting in device destruction. More specifically, if current flowing through the inductor is suddenly turned off, counter ElectroMotive Force (EMF) may occur to induce very high potential across (e.g., source-drain terminals) the MOS-gated transistor. The potential induced across the MOS-gated transistor may exceed a breakdown voltage of the MOS-gated transistor. As a result, device destruction occurs.

FIG. 1A is a cross-sectional view of a conventional insulated gate bipolar transistor (IGBT) 100. FIG. 1B shows density of hole current during UIS in IGBT 100.

In FIG. 1A, an n⁺-type buffer layer 104 and an n⁻-type epitaxial layer 106 extend over a p⁺-type substrate 102. The p⁺-type substrate 102 is the collector region, and the n⁻-type epitaxial layer 106 is the drift region. The p⁻-type well region 108 is formed in a predetermined upper portion of the n⁻-type epitaxial layer 106. An n⁺-type emitter region 110 is formed in a predetermined upper portion of the p⁻-type well region 108 and is surrounded by the p⁻-type well region 108. In a surface portion “A” of the p⁻-type well region 108, between the n⁺-type emitter region 110 and the n⁻-type epitaxial layer 106, there is a channel region where a channel is formed under certain biasing conditions.

A gate electrode 114 extends over the channel region and the n⁻-type epitaxial layer 106, and overlaps the n⁺-type emitter region 110. Gate electrode 114 is insulated from these underlying regions by a gate insulating layer 112. An emitter electrode 116 is disposed on a surface area of each of the n⁺-type emitter region 110 and the p⁻-type well region 108 to electrically contact these two regions. Although not shown in the drawings, gate electrode 114 is electrically insulated from emitter electrode 116 by an interlayer dielectric. Also, a collector electrode 118 is disposed under the p⁺-type substrate 102 to electrically contact the p⁺-type substrate 102.

In IGBT 100, when UIS occurs, the density of hole current is high next to the n⁺-type emitter region 110 and below the p⁻-type well region 108 (denoted by a1 and b1 in FIG. 1B), but is low along the side of the p⁻-type well region 108 (denoted by c1 in FIG. 1B). This is because breakdown first occurs at the bottom of the p⁻-type well region 108. Thus, the amount of current flowing into the bottom of the n⁺-type emitter region 110 is reduced so that the amount of voltage drop decreases in the p⁻-type well region 108 under the n⁺-type emitter region 110. As a result, the operation of a parasitic npn transistor made up of the n⁺-type emitter region 110, the p⁻-type well region 108, and the n⁻-type epitaxial layer 106, is suppressed, thus increasing the transistor UIS capability.

Although IGBT 100 has the advantage of high UIS capability, during normal operation, JFET resistance elements may increase next to portion “A” due to a bottleneck effect. Thus, the saturation voltage increases. To solve this problem, a distance between adjacent p⁻-type well regions 108 may be increased. However, this increases the size of the entire device and the integration density decreases.

FIG. 1C is a graph of collector-emitter voltage (V_{CE}) and collector current (I_{C}) versus time during UIS in IGBT 100 of FIG. 1A. Before time t1, as gate electrode 114 is being turned on by applying a predetermined bias voltage, the collector current (I_{C}) (indicated by “100i”) increases at a slow rate. However, when UIS occurs at a turn-off point at time t1, energy stored in an inductor is supplied to IGBT 100 so that the collector-emitter voltage (V_{CE}) (indicated by “100V”) sharply increases. The collector current (I_{C}) at time t1 when the UIS occurs is approximately 22 A. Meanwhile, the collector current (I_{C}) gradually decreases and then starts increasing again at a predetermined time t2. That is, at t2, device destruction occurs due to the UIS.

FIG. 2A is a cross-sectional view of a conventional IGBT 200 with a JFET region. FIG. 2B shows the density of hole current during UIS in the IGBT 200 of FIG. 2A when UIS occurs.

IGBT 200 in FIG. 2A is the same as IGBT 100 in FIG. 1A, except that an n-type JFET region 210 is formed in an upper region of the n⁻-type epitaxial layer 106. The n-type JFET region 210 forms a pn junction 211 with the p⁻-type well region 108. The impurity concentration of n-type JFET region 210 is higher than that of the n⁻-type epitaxial layer 106.

When IGBT 200 operates normally, a bottleneck does not occur next to the surface of IGBT 200 under a gate electrode 114 due to a low resistance of JFET region 210. However, as shown in FIG. 2B, when UIS occurs, the density of hole current is highest adjacent to the n⁺-type emitter region 110 (indicated by “a2”), high to some extent in an area (indicated by “b2”) of JFET region 210 to the side of the p⁻-type well region 108, and lowest in an area (indicated by “c2”) to the bottom of the p⁻-type well region 108. That is, breakdown occurs at the side of the p⁻-type well region 108 earlier than at the bottom thereof. Thus, a larger amount of hole current flows through the side of the p⁻-type well region 108. As a result, as a larger amount of hole current flows into the bottom of the n⁺-type emitter region 110, operation of a parasitic npn transistor is more easily activated, thus degrading its UIS capability.

FIG. 2C is a graph of collector-emitter voltage (V_{CE}) and collector current (I_{C}) versus time in IGBT 200 of FIG. 2A. Profiles of collector-emitter voltage (V_{CE}) (indicated by “200V”) and collector current (I_{C}) (indicated by “200i”) of IGBT 200 are similar to those of IGBT 100 shown in FIG. 1A. However, in IGBT 200, the collector current at the point in time when UIS occurs is approximately 0.18 A, which is much lower than the 22 A for IGBT 100 shown in FIG. 1A. It can thus be seen that IGBT 200 has a lower UIS capability than IGBT 100.

Thus, there is a need for an improved MOS-gated transistor.

### BRIEF SUMMARY OF THE INVENTION

In accordance with the present invention, a MOS-gated transistor has a structure which smoothes current flow therein during UIS so as to improve UIS capability yet suppress a bottleneck adjacent to its surface in normal switching-on operations.

In accordance with an embodiment of the present invention, a transistor includes a semiconductor substrate forming a collector region. A drift region of a first conductivity type extends over the semiconductor substrate. First and second well regions of a second conductivity each extends from an upper surface of the drift region into and terminates within the drift region. The first well region is coupled to an emitter terminal while the second well region floats. The first and second well regions are separated by an impurity region of the first conductivity type such that each of the first and second well regions forms a separate pn junction with the impurity region.

In one embodiment, the first and second well regions and the impurity region therebetween are configured such that when the separate pn junctions are reverse biased a boundary of a depletion region in the drift region is substantially flat.

In another embodiment, the impurity region has an impurity concentration higher than that of the drift region.

In another embodiment, the transistor further includes an emitter region of the first conductivity type formed in an upper portion of the first well region. The emitter region is coupled to the emitter terminal.

In another embodiment, the transistor further includes a gate terminal extending over but being insulated from a surface area of the first well region between the emitter region and the impurity region.

In another embodiment, the transistor has a buffer layer between the semiconductor substrate and the drift region and having the same conductivity type as the drift region, the buffer layer having a higher impurity concentration than the impurity region.

In another embodiment, a distance between the first well region and the floating well region is in a range of 3 μm to 6 μm.

In another embodiment, the thickness of the drift region is in a range of 40 μm to 120 μm.

In accordance with another embodiment of the present invention, a method of forming a transistor is as follows. A drift region of a first conductivity type is formed over a semiconductor substrate, wherein the semiconductor substrate forms a collector region. A first well region of a second conductivity type is formed in the drift region such that the first well region extends from an upper surface of the drift region into and terminates within the drift region. A second well region of the second conductivity is formed in the drift region such that the second well region extends from an upper surface of the drift region into and terminates within the drift region. The first well region is coupled to an emitter terminal while the second well region floats. An impurity region of the first conductivity type is formed in the drift region between the first and second well regions so that each of the first and second well regions forms a separate pn junction with the impurity region.

### BRIEF DESCRIPTION OF THE DRAWINGS

The above and other features and advantages of the present invention will become more apparent by describing in detail preferred embodiments thereof with reference to the attached drawings in which:

FIG. 1A is a cross-sectional view of a conventional insulated gate bipolar transistor (IGBT);

FIG. 1B shows the density of hole current during UIS in the IGBT of FIG. 1A;

FIG. 1C is a graph of collector-emitter voltage (V_{CE}) and collector current (I_{C}) versus time in the IGBT of FIG. 1A;

FIG. 2A is a cross-sectional view of a conventional IGBT with a JFET region;

FIG. 2B shows the density of hole current in the IGBT of FIG. 2A when UIS occurs;

FIG. 2C is a graph of collector-emitter voltage (V_{CE}) and collector current (I_{C}) versus time in the IGBT of FIG. 2A.

FIG. 3 is a cross-sectional view of an IGBT with improved UIS capability in accordance with an embodiment of the present invention;

FIGS. 4A through 4C show the density of hole current in different variations of the IGBT of FIG. 3 when UIS occurs;

FIG. 5 is a circuit diagram of a UIS test circuit used for simulating an IGBT;

FIG. 6 is a graph of collector voltage and collector current versus time, which is obtained by a simulation using the UIS test circuit of FIG. 5;

FIG. 7 is a graph showing the density of hole current flowing in a horizontal direction of an n⁺-type emitter, which is obtained by a simulation using the UIS test circuit of FIG. 5;

FIG. 8 shows density of hole current and the maximum density of hole current at an edge of the n⁺-type emitter region during UIS; and

FIGS. 9 through 14 are graphs showing electrical characteristics of various MOS-gated transistors including that of the present invention.

### DETAILED DESCRIPTION OF THE INVENTION

The present invention will now be described more fully with reference to the accompanying drawings. This invention may, however, be embodied in many different forms and thus should not be construed as being limited to the embodiments set forth herein.

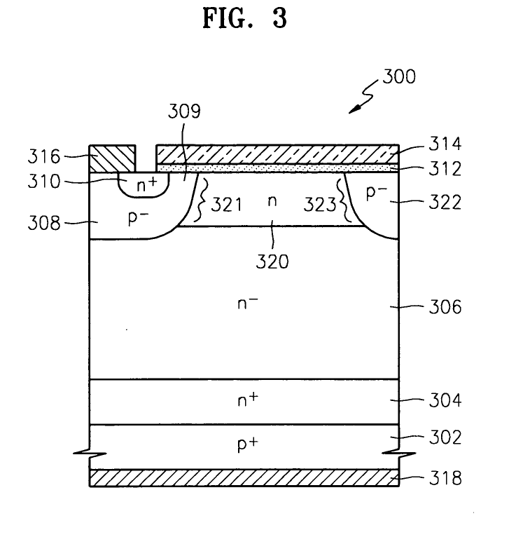

FIG. 3 is a cross-sectional view of an IGBT with improved UIS capability in accordance with an embodiment of the present invention. An n⁺-type buffer layer 304 and an n⁻-type epitaxial layer 306 are sequentially formed over a p⁺-type substrate 302 using conventional processing methods. The n⁻-type epitaxial layer 306 is preferably formed to a thickness of approximately 40 μm to 60 μm. However, for example, in non-punch-through (NPT) IGBTs without the n⁺-type buffer layer 304, the n⁻-type epitaxial layer 306 may be formed to a thickness of up to 120 μm. The p⁺-type substrate 302 is the collector region, and the n⁻-type epitaxial layer 306 is the drift region. A p⁻-type well region 308 is formed in a predetermined upper region of the n-type epitaxial layer 306. An n⁺-type emitter region 310 is formed in a predetermined upper portion of the p⁻-type well region 308 and is surrounded by the p⁻-type well region 308. The p⁻-type well region 308 and the n⁺-type emitter region 310 are formed using conventional processing methods. In a surface portion of the p⁻-type well region 308 between the n⁺-type emitter region 310 and the n⁻-type epitaxial layer 306, there is a channel region 309 where a channel is formed under certain biasing conditions.

An n-type JFET region 320 is disposed in an upper portion of the n⁻-type epitaxial layer 306 using conventional processing techniques. The n-type JFET region 320 forms a pn junction 321 with the p⁻-type well region 308. The impurity concentration of the n-type JFET region 320 is higher than that of the n⁻-type epitaxial layer 306. A p⁻-type floating well region 322 is also disposed in an upper portion of the n⁻-type epitaxial layer 306 using conventional processing techniques. The n-type JFET region 320 forms a second pn junction 321 with the p⁻-type floating well region 322. The p⁻-type floating well region 322 is spaced apart from the p⁻-type well region 308 by the n-type JFET region 320. In a 600V IGBT embodiment, a distance between the p⁻-type floating well region 322 and the p⁻-type well region 308 is approximately 3 μm to 6 μm and becomes longer with an increase in the device voltage rating.

A gate electrode 314 extends over channel region 309, the n⁻-type epitaxial layer 306, and the p⁻-type floating well region 322, and overlaps n⁺-type emitter region 310. Gate electrode 314 is insulated from these underlying regions by a gate insulating layer 312. In an alternate embodiment, gate electrode 314 does not extend over the n⁻-type epitaxial layer 306 and the p⁻-type floating well region 322. Gate electrode 314 and the underlying gate dielectric 314 are formed using conventional processing techniques.

An emitter electrode 316 is disposed on a surface area of each of the n⁺-type emitter region 310 and the p⁻-type well region 308 to electrically contact these two regions. Although not shown in the drawings, gate electrode 314 is electrically isolated from emitter electrode 316 by an interlayer dielectric. Also, a collector electrode 318 is disposed under the p⁺-type substrate 302 to electrically contact the p⁺-type substrate 302.

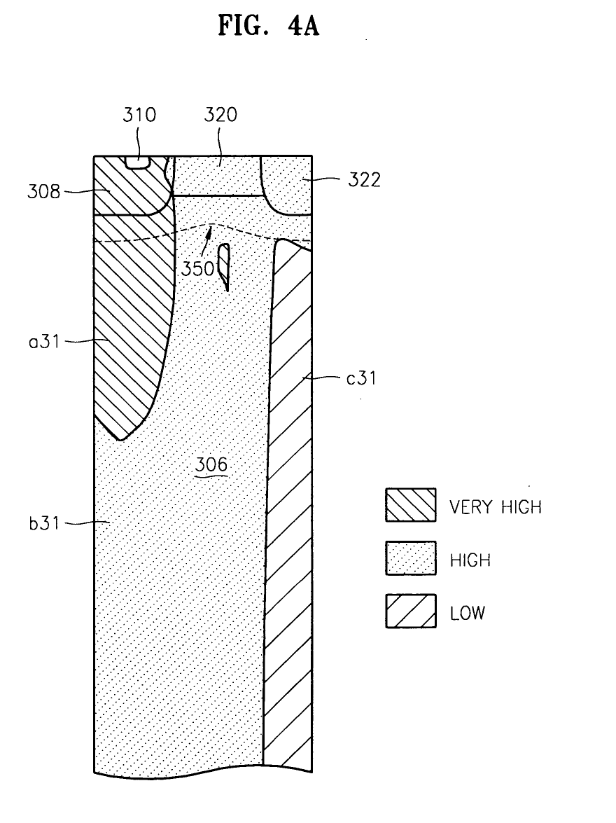

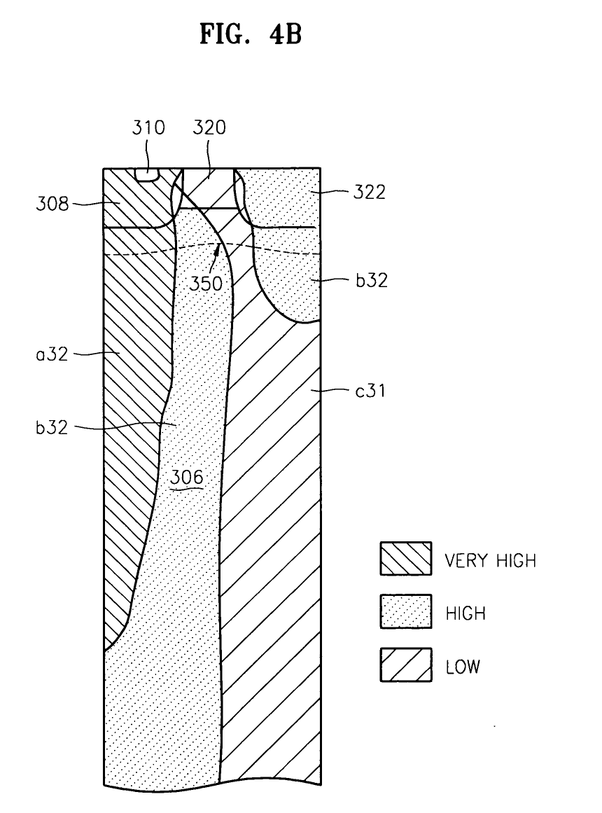

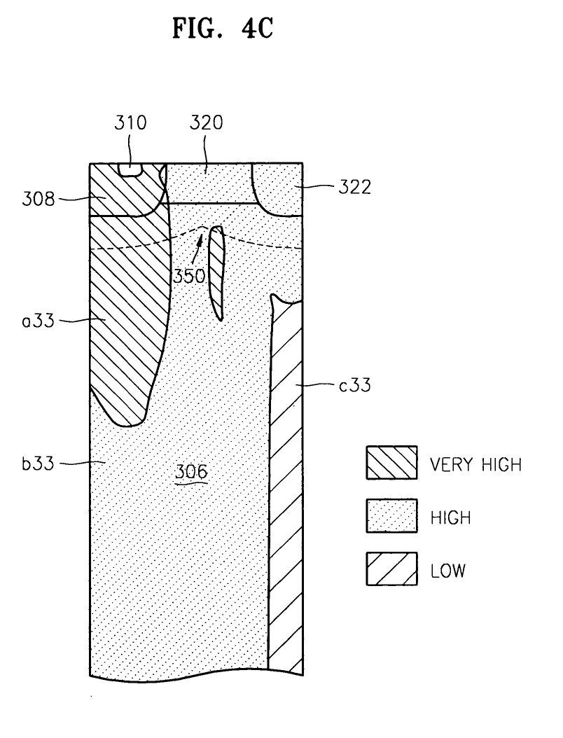

FIGS. 4A through 4C show the density of the hole current in different variations of the IGBT in FIG. 3. Specifically, FIG. 4A shows the variation where the p⁻-type floating well region 322 is spaced apart from the p⁻-type well region 308 by a predetermined distance or more, FIG. 4B shows the variation where the p⁻-type floating well region 322 is spaced apart from the p⁻-type well region 308 by a relatively short distance, and FIG. 4C shows the variation where the p⁻-type floating well region 322 is spaced apart from the p⁻-type well region 308 same as that in FIG. 4A but the n⁻-type epitaxial layer 306 is formed to be 10 μm thinner than that in the other two variations.

In all three variations, as shown in FIGS. 4A through 4C, hole current is uniformly distributed. That is, most hole current moves through a junction between the n⁻-type epitaxial layer 306 and the p⁻-type well region 308. In particular, most hole current flows through the bottom of the p⁻-type well region 308 with the largest area. This is because the p⁻-type floating well region 322 suppresses the occurrence of breakdown at the surface of the device. If the p⁻-type floating well region 322 is not formed, a relatively high concentration of impurity ions in the n-type JFET region 320 causes an electric field crowding. Thus, as described above, breakdown occurs at the surface of the device and a large amount of current flows along the surface and channel region 309.

If UIS occurs, a reverse bias voltage is applied between the n⁻-type epitaxial layer 306 and the p⁻-type well region 308 and between the n-type JFET region 320 and the p⁻-type well region 308. Likewise, a reverse bias voltage is applied between the n⁻-type epitaxial layer 306 and the p⁻-type floating well region 322 and between the n-type JFET region 320 and the p⁻-type floating well region 322. Thus, depletion regions start to extend from these interface regions in both directions. As the depletion regions extend in both directions, depletion regions extending toward the n⁻-type epitaxial layer 306 overlap each other such that a planar depletion region boundary 350 is formed in the n⁻-type epitaxial layer 306. As is well known, an electric field crowding is weaker in a planar depletion region boundary than others, such as a cylindrically-shaped or spherically-shaped depletion region boundaries. Accordingly, breakdown does not occur at the surface of the device because of formation of the planar boundary 350, thus improving the transistor UIS capability.

As shown in FIG. 4B, when a distance between the p⁻-type floating well region 322 and the p⁻-type well region 308 is made narrower, the depletion regions overlap even more. Therefore, the planar depletion region boundary 350 becomes flatter so as to further improve UIS capability.

Simulation results of a UIS test circuit will be described next.

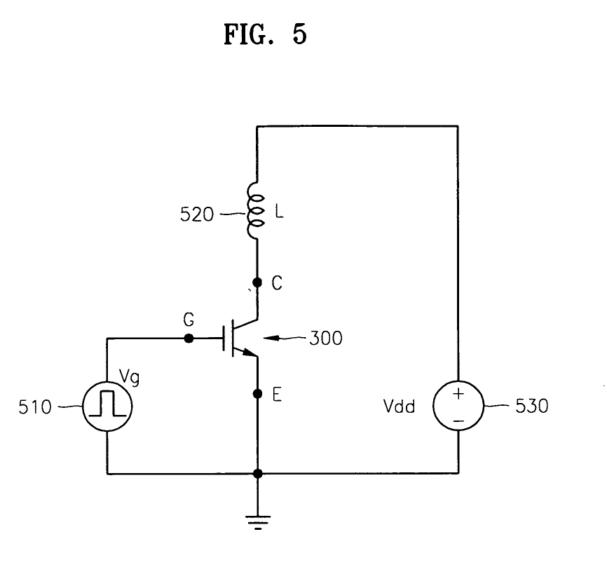

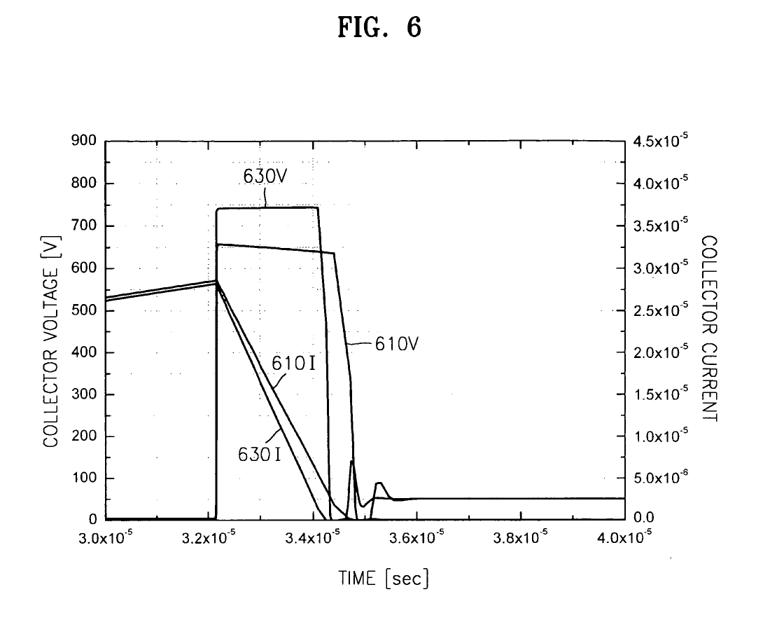

FIG. 5 shows a UIS test circuit used for simulating an IGBT, and FIGS. 6 through 8 are graphs showing simulation results of the UIS test circuit.

Referring to FIG. 5, a gate driving power supply 510 for generating a gate driving voltage is connected to a gate terminal G of an IGBT 300, which is a device under test (DUT). An inductive load 520 having a predetermined inductance L is serially connected to a collector terminal C of IGBT 300. An emitter terminal E of IGBT 300 is grounded. Also, inductive load 520 is serially connected to an external power supply 530 for applying a voltage Vdd.

To test this test circuit, the gate driving power supply 510 applies a gate driving voltage Vg to the gate terminal of the IGBT 300 for a predetermined amount of time. While the gate driving voltage Vg is being applied, the IGBT remains turned on. In this state, if the gate driving voltage Vg is not applied any longer, i.e., if the IGBT 300 is turned off, an abrupt break in the drain current occurs. Because the magnetic field of the inductor 520 can not instantaneously collapse, a voltage is induced in the collector of the IGBT 300. The induced potential easily surpasses an avalanche breakdown voltage. During the avalanche, the induced voltage is clamped at a value of the avalanche breakdown voltage and the current stored in the inductor 520 decreases linearly. However, in this case, if a parasitic bipolar transistor is turned on due to secondary breakdown, the IGBT 300 may be destroyed due to UIS.

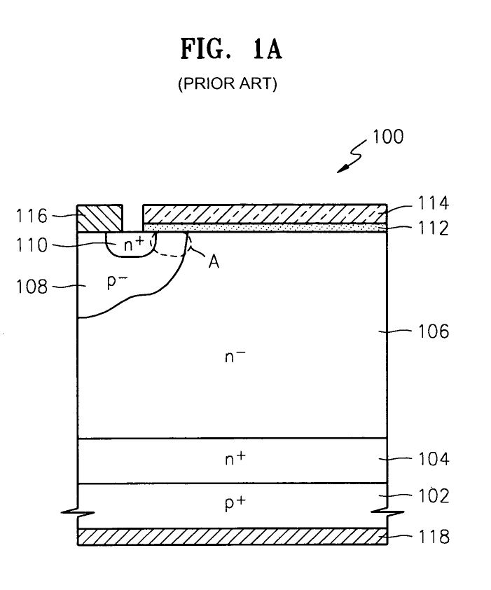

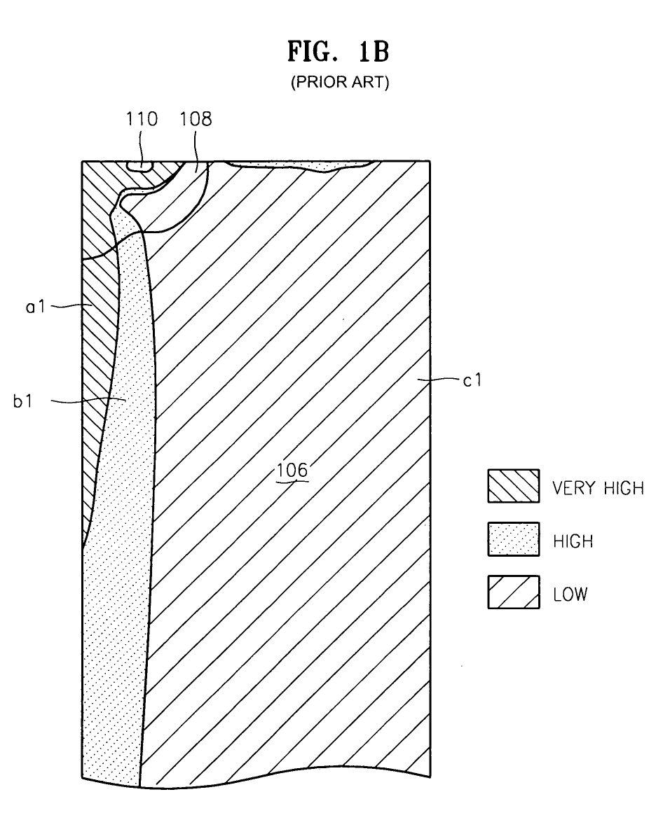

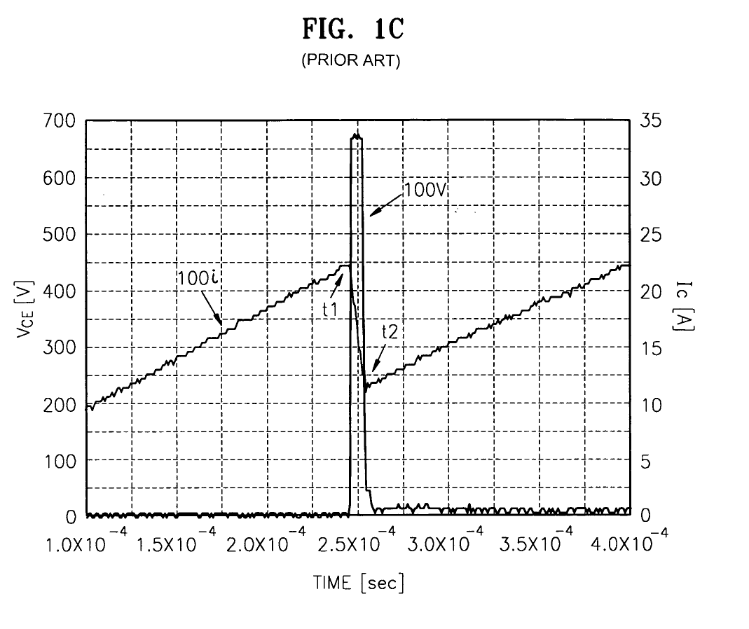

FIG. 6 is a graph of collector voltage (denoted by 610V and 630V) and collector current (denoted by 610I and 630I) versus time in IGBT 100 of FIG. 1A (610V and 610I) and IGBT 300 of FIG. 3 (630V and 630I). In both IGBTs, the collector current decreases to approximately 0. Thus, there is no device destruction due to UIS. However, in IGBT 300 of FIG. 3, the breakdown voltage (630V) is higher and the current (630I) decreases in a shorter amount of time than that in IGBT 100 of FIG. 1A. This is because, assuming that all energy stored in an inductor is dissipated through IGBT 300 without consideration of resistance of an external circuit, different devices have different breakdown voltages for the same energy.

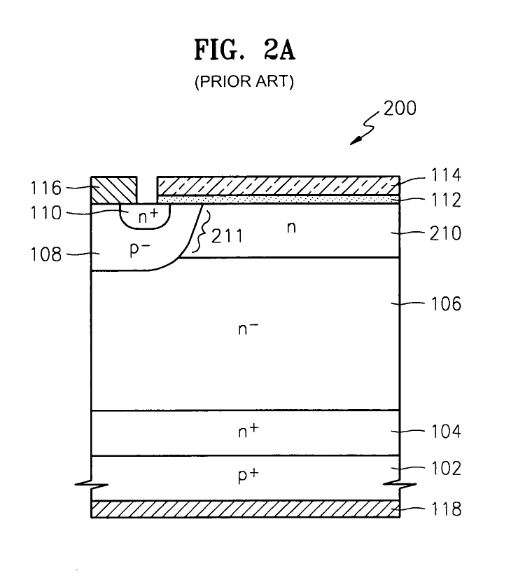

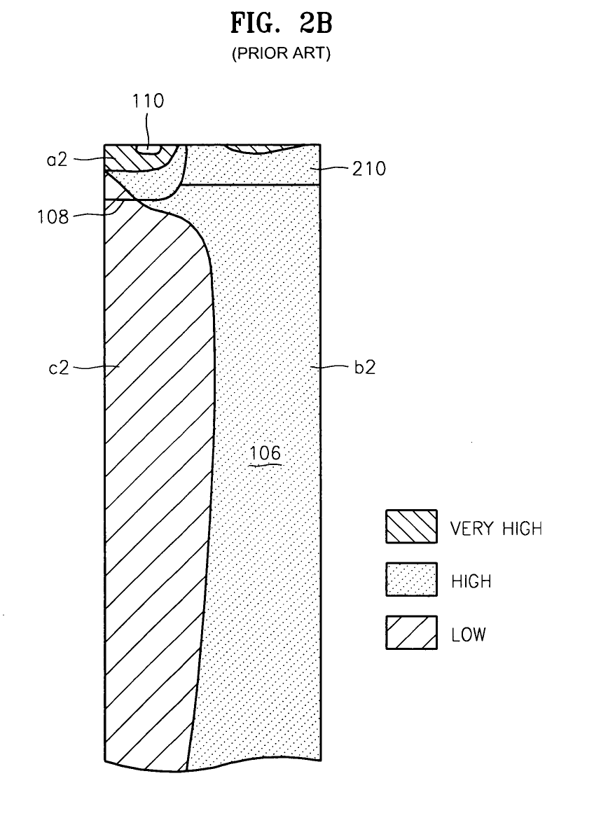

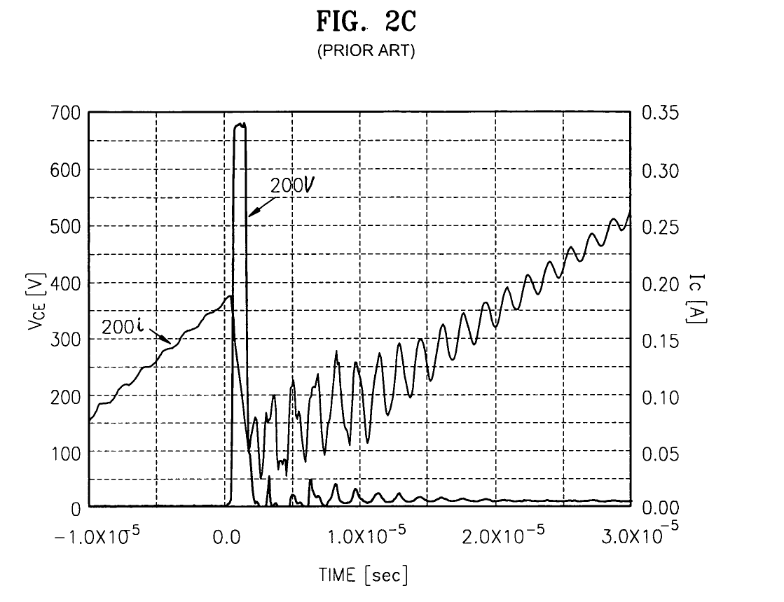

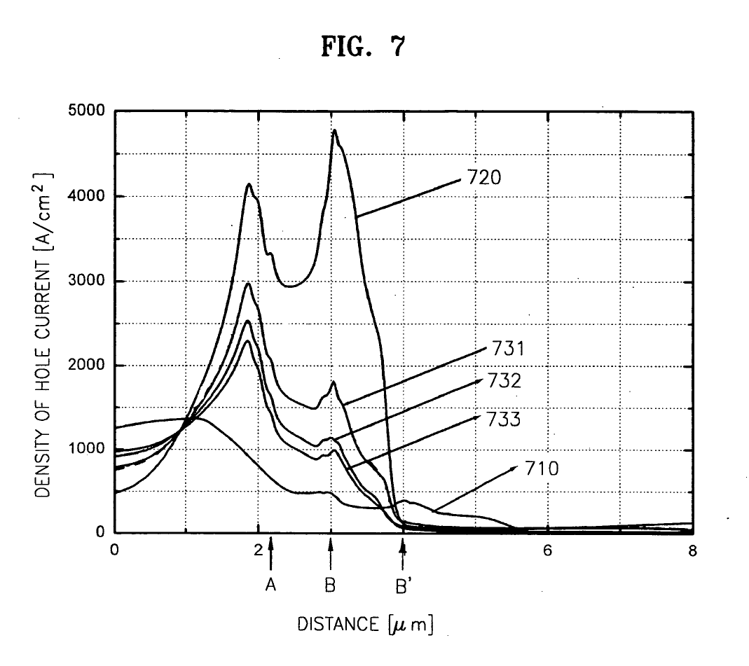

Next, FIG. 7 shows the density of hole current flow in a horizontal direction of the n⁺-type emitter region 310 adjacent to the surface of the IGBT. In IGBT 100 of FIG. 1A (denoted by 710), the density of hole current was highest on the left of an interface point (denoted by “B′”) between the n⁺-type emitter region 110 and the p-type well region 108, i.e., around the center of the n⁺-type emitter region 110. That is, this leads to the density of hole current shown in FIG. 1B. However, the maximum density of hole current was lowest of all cases. On the other hand, in IGBT 200 of FIG. 2A (denoted by 720), the density of hole current was highest at an interface point (denoted by “B”) between the n⁺-type emitter region 110 and the p⁻-type well region 108. For reference, the interface points (B′, B) in the IGBTs of FIGS. 1A and 2A are positionally different because a horizontal width (20 μm) of IGBT 100 shown in FIG. 1A differs from that (12 μm) of IGBT 200 shown in FIG. 2A.

In IGBT 300 as shown in FIG. 3 (denoted by 731, 732, and 733), the density of hole current was highest inside the n⁺-type emitter region 310 (at a distance of approximately 2 μm), not at an interface point (denoted by “A”) between the n⁺-type emitter region 310 and the p⁻-type well region 308. In all cases (731, 732, and 733), the maximum density of hole current was higher than that of IGBT 100 shown in FIG. 1A and lower than that of IGBT 200 shown in FIG. 2A. Specifically, when a distance between the p⁻-type well region 308 and the p⁻-type floating well region 322 was approximately 4 μm to 5 μm (denoted by 731), the maximum density of hole current was highest. As the distance between the p⁻-type well region 308 and the p⁻-type floating well region 322 was reduced by approximately 1 μm (denoted by 732) and further reduced by approximately 2 μm (denoted by 733), the maximum density of hole current became lower and lower.

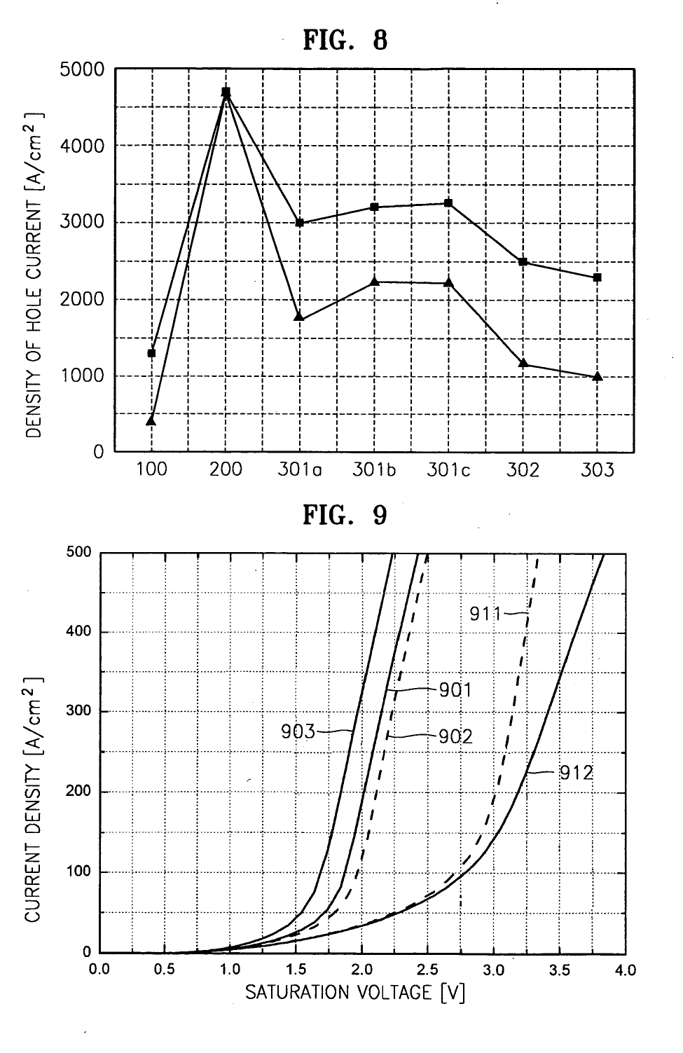

FIG. 8 shows the density of hole current (denoted by “▴”) and the maximum density of hole current (denoted by “▪”) at an edge of the n⁺-type emitter region 110. The density of hole current and the maximum density of hole current at the edge of the n⁺-type emitter region 110 were lowest in IGBT 100 of FIG. 1A. Meanwhile, the density of hole current and the maximum density of hole current at the edge of the n⁺-type emitter region 110 were highest in IGBT 200 of FIG. 2A. In IGBTs 301a through 301c as shown in FIG. 3, the density of hole current and the maximum density of hole current were higher than in IGBT 100 of FIG. 1A and lower than in IGBT 200 of FIG. 2A. In particular, in cases where a thickness of the n⁻-type epitaxial layer 306 was 40 μm and 45 μm (301b and 301c, respectively), the density of hole current and the maximum density of hole current were higher than in a case where a thickness of the n⁻-type epitaxial layer 306 was approximately 50 μm (301a). Accordingly, as the thickness of the n-type epitaxial layer 306 decreases, the UIS capability becomes lower but other electrical characteristics, such as saturation voltage and a switching characteristic, improve. In another embodiment, as a distance between the p⁻-type well region 308 and the p⁻-type floating well region 322 is reduced by approximately 1 μm and further reduced by approximately 2 μm (denoted by 302 and 303, respectively), the density of hole current and the maximum density of hole current at the edge of the n⁺-type emitter region 110 are further reduced. This is because as a distance between the p⁻-type well region 308 and the p-type floating well region 322 becomes shorter, a flatter planar depletion region boundary 350 is formed in the n⁻-type epitaxial layer 306.

FIGS. 9 through 14 are graphs showing electrical characteristics of various MOS-gated transistors including that of the present invention. FIG. 9 is a graph of current density versus saturation voltage. Reference numeral 901 corresponds to IGBT 200 shown in FIG. 2A, and reference numerals 902 and 903 correspond to IGBT 300 shown in FIG. 3. Specifically, reference numeral 902 corresponds to the case where a distance between the p⁻-type well region 308 and the p⁻-type floating well region 322 is reduced by approximately 1 μm, and reference numeral 903 corresponds to the case where a distance between the p⁻-type well region 308 and the p⁻-type floating well region 322 is reduced by approximately 1 μm and simultaneously a thickness of the n⁻-type epitaxial layer 306 is reduced by 10 μm. All cases exhibit similar variation of current density with respect to saturation voltage. However, when a distance between the p⁻-type well region 308 and the p⁻-type floating well region 322 is reduced by approximately 1 μm and simultaneously a thickness of the n⁻-type epitaxial layer 306 is reduced by 10 μm (denoted by 903), the electrical characteristic is most optimum.

Reference numeral 912 denotes a case where an electric short occurs between the p⁻-type floating well region 322 and an emitter electrode. Also, reference numeral 911 denotes a case where an n⁺-type region is formed in the p⁻-type floating well region 322 and an electric short occurs between the p⁻-type floating well region 322 and an emitter electrode. In the case denoted by 911, the electrical characteristic is better than in the case denoted by 912.

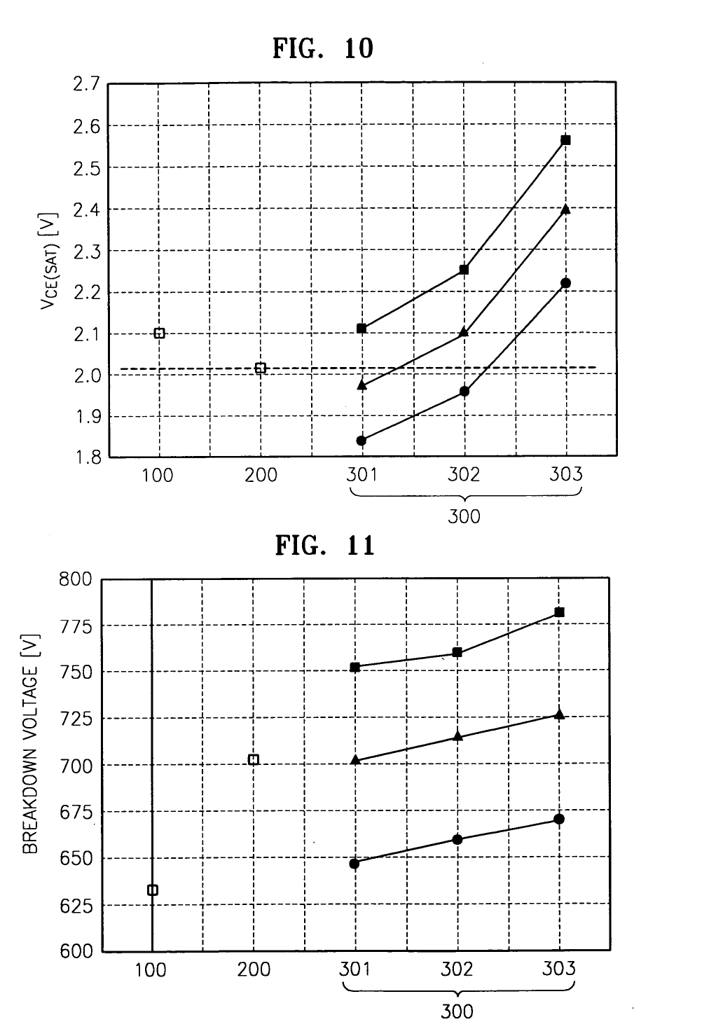

FIG. 10 is a graph of collector-emitter saturation voltage (V_{CE(SAT)}) at a current density of 150A/cm². In IGBT 200 of FIG. 2A, the collector-emitter saturation voltage (V_{CE(SAT)}) is approximately 2.0 V, while in IGBT 100 of FIG. 1A, the collector-emitter saturation voltage (V_{CE(SAT)}) is slightly higher than 2.0 V (denoted by “□”). On the other hand, in IGBT 300, the collector-emitter saturation voltage (V_{CE(SAT)}) varies according to the distance between the p⁻-type well region 308 and the p⁻-type floating well region 322 and/or the thickness of the p⁻-type well region 308. Specifically, when the distance between the p⁻-type well region 308 and the p⁻-type floating well region 322 is approximately 4 μm to 5 μm (denoted by 301), the collector-emitter saturation voltage (V_{CE(SAT)}) is lowest and the electrical characteristic is best. As the distance between the p⁻-type well region 308 and the p⁻-type floating well region 322 is reduced by approximately 1 μm (denoted by 302) and further reduced by approximately 2 μm (denoted by 303), the collector-emitter saturation voltage (V_{CE(SAT)}) increases. Also, as the thickness of the p⁻-type well region 308 becomes smaller, i.e., from 50 μm (denoted by “▪”) to 45 μm (denoted by “▴”), and to 40 μm (denoted by “●”), the collector-emitter saturation voltage (V_{CE(SAT)}) reduces and the electrical characteristic improves.

FIG. 11 shows variation of breakdown voltage. IGBT 100 of FIG. 1A has the lowest breakdown voltage, whereas IGBT 200 of FIG. 2A has a relatively high breakdown voltage (denoted by “□”). In IGBT 300, the breakdown voltage varies according to the distance between the p⁻-type well region 308 and the p⁻-type floating well region 322 and/or the thickness of the p⁻-type well region 308. Specifically, when the distance between the p⁻-type well region 308 and the p⁻-type floating well region 322 is approximately 4 μm to 5 μm (denoted by 301), the breakdown voltage is relatively low. As the distance between the p⁻-type well region 308 and the p⁻-type floating well region 322 is reduced by approximately 1 μm (denoted by 302) and further reduced by approximately 2 μm (denoted by 303), the breakdown voltage increases. However, the three cases do not show major differences.

As the thickness of the p-type well region 308 becomes smaller, i.e., from 50 μm (denoted by “▪”) to 45 μm (denoted by “▴”), and to 40 μm (denoted by “●”), the breakdown voltage reduces. There is a relatively large difference between these cases.

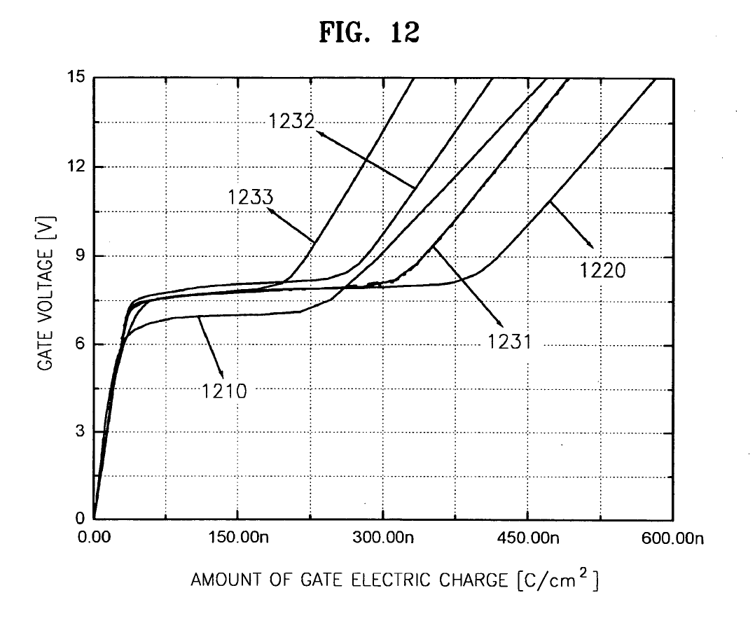

FIG. 12 shows the amount of gate electric charge. Generally, when a certain gate voltage (e.g., 15V) is applied to drive a MOS-gated transistor, the amount of gate electric charge, which indicates the amount of electric charge stored in a gate insulating layer, is preferred to be as small as possible. As shown in FIG. 12, IGBT 100 of FIG. 1A (denoted by 1210) shows a better electrical characteristic than IGBT 200 of FIG. 2A (denoted by 1230). In IGBT 300, when the distance between the p⁻-type well region 308 and the p⁻-type floating well region 322 is approximately 4 μm to 5 μm (denoted by 1231), the amount of gate electric charge is relatively large. As the distance between the p⁻-type well region 308 and the p⁻-type floating well region 322 is reduced by approximately 1 μm (denoted by 1232) and further reduced by approximately 2 μm (denoted by 1233), the amount of gate electric charge reduces, thus resulting in improved electrical characteristic. As the amount of gate electric charge reduces, the gate can be charged by a smaller amount of current. Therefore, a gate driving circuit can have a simpler construction.

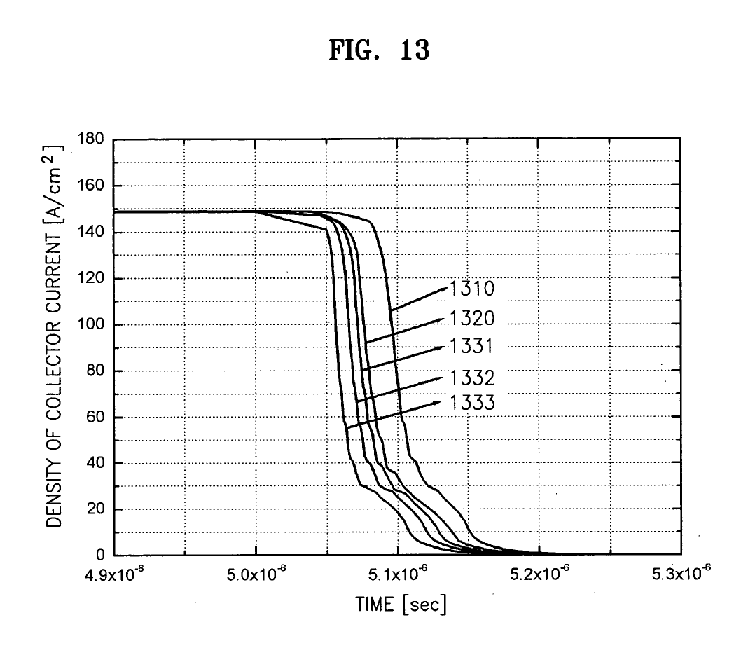

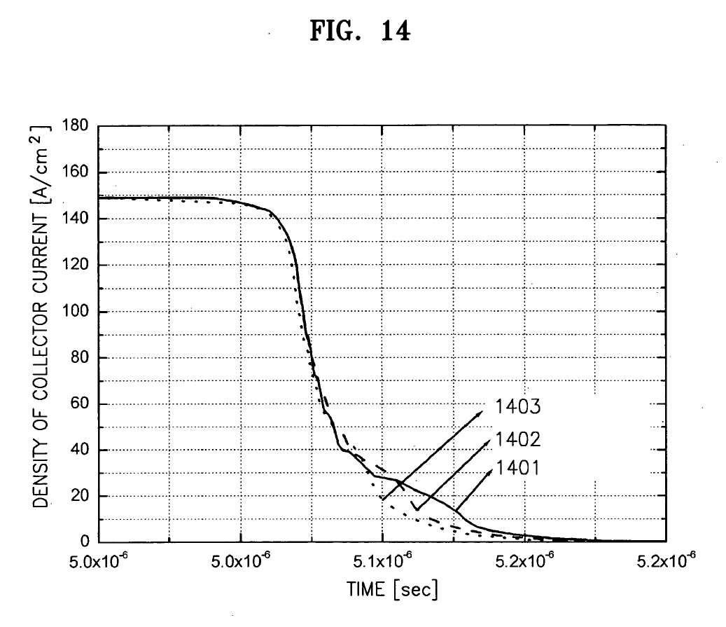

FIG. 13 is a graph of density of collector current versus time in a turn-off operation. In IGBT 100 of FIG. 1A (denoted by 1310), the time required for reducing the density of collector current in a turn-off operation is longest, and thus the turn-off delay time is also longest. On the other hand, in IGBT 200 of FIG. 2A (denoted by 1320), the turn-off delay time is shorter. Further, in IGBT 300 of the present invention (denoted by 1331, 1332, and 1333), the turn-off delay time is even shorter. Specifically, when the distance between the p⁻-type well region 308 and the p⁻-type floating well region 322 is approximately 4 μm to 5 μm (denoted by 1331), the turn-off delay time is relatively long. As the distance between the p⁻-type well region 308 and the p⁻-type floating well region 322 is reduced by approximately 1 μm (denoted by 1332) and further reduced by approximately 2 μm (denoted by 1333), the turn-off delay time is reduced.

FIG. 14 is a graph of density of collector current versus time in a turn-off operation. When the thickness of the p-type well region 308 is made smaller, i.e., from 50 μm (denoted by 1401) to 45 μm (denoted by 1402), and to 40 μm (denoted by 1403), all three cases show similar characteristics. That is, a variation in thickness of the p⁻-type well region 308 has little influence on the turn-off delay time. However, the variation in thickness of the p⁻-type well region 308 has some influence on a tail current characteristic. As the thickness of the p⁻-type well region 308 decreases, the tail current becomes smaller and the electrical characteristic improves.

As explained above, the MOS-gated transistor, in accordance with the present invention, includes a p-type well region, and a p-type floating well region disposed parallel to the p-type well region, between which a JFET region is interposed. Thus, a bottleneck phenomenon can be prevented at the bottom of a gate electrode when carriers move normally. Also, a depletion region having a flat planar boundary can be formed under UIS, thus improving UIS capability. Also, although the invention has been described primarily in the context of IGBTs, the invention is not limited to IGBTs. Same features and advantages can be obtained by applying the principles of the present invention to other types of MOS-gated transistors such as power MOSFETs. For example, the IGBT embodiment shown in FIG. 3 can be converted to a MOSFET by using an n⁺-type substrate instead of the p⁺-type substrate 302 shown in FIG. 3. The n+-type buffer layer 304 may be eliminated if desired. In such MOSFET structure, the n⁺-type substrate functions as the drain, and the n⁺-type region 310 functions as the source.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed is:

1. A MOS-gated transistor comprising:
a semiconductor substrate forming a collector region;
a drift region of a first conductivity type extending over the semiconductor substrate;
a first well region of a second conductivity type formed in an upper portion of the drift region, the first well region being coupled to an emitter terminal;
an impurity region of the first conductivity type formed in an upper portion of the drift region adjacent to the first well region so as to form a pn junction with the first well region, the impurity region having an impurity concentration higher than that of the drift region;
a floating well region of the second conductivity type formed in an upper portion of the drift region adjacent to the impurity region so as to form a pn junction with the impurity region, the floating well region being spaced apart from the first well region by the impurity region;
an emitter region formed in an upper portion of the first well region;
a gate insulating layer extending over a surface area of the first well region between the emitter region and the impurity region; and
a gate electrode extending over the gate insulating layer.

2. The MOS-gated transistor of claim 1 further comprising a buffer layer between the semiconductor substrate and the drift region and having the same conductivity type as the drift region.

3. The MOS-gated transistor of claim 2 wherein the buffer layer has a higher impurity concentration than the impurity region.

4. The MOS-gated transistor of claim 1 wherein a distance between the first well region and the floating well region is in a range of 3 μm to 6 μm.

5. The MOS-gated transistor of claim 1 wherein the thickness of the drift region is in a range of 40 μm to 120 μm.

6. The MOS-gated transistor of claim 1, wherein the semiconductor substrate has the first conductivity type.

7. The MOS-gated transistor of claim 1, wherein the semiconductor substrate has the second conductivity type.

8. The MOS-gated transistor of claim 1, wherein the emitter region has the first conductivity type.

9. A MOS-gated transistor comprising:
a semiconductor substrate coupled to a collector terminal;
an epitaxial layer of a first conductivity type extending over the semiconductor substrate;
a first well region of a second conductivity type formed in an upper portion of the epitaxial layer, the first well region being coupled to an emitter terminal;
an impurity region of the first conductivity type formed in an upper portion of the epitaxial layer adjacent to the first well region so as to form a first pn junction with the first well region;
a floating well region of the second conductivity type formed in an upper portion of the epitaxial layer adjacent to the impurity region so as to form a second pn junction with the impurity region, the floating well region being spaced apart from the first well region by the impurity region such that when the first and second pn junctions are reverse biased a boundary of a depletion region in the epitaxial layer is substantially flat;
an emitter region formed in an upper portion of the first well region; and
a gate terminal extending over but being insulated from a surface area of the first well region between the emitter region and the impurity region.

10. The MOS-gated transistor of claim 9 further comprising a buffer layer between the semiconductor substrate and the epitaxial layer and having the same conductivity type as the epitaxial layer.

11. The MOS-gated transistor of claim 10 wherein the buffer layer has a higher impurity concentration than the impurity region.

12. The MOS-gated transistor of claim 9 wherein a distance between the first well region and the floating well region is in a range of 3 μm to 6 μm.

13. The MOS-gated transistor of claim 9 wherein the thickness of the drift region is in a range of 40 μm to 120 μm.

14. A transistor comprising:
a semiconductor substrate forming a collector region;
a drift region of a first conductivity type extending over the semiconductor substrate; and
first and second well regions of a second conductivity each extending from an upper surface of the drift region into and terminating within the drift region, the first well region being coupled to an emitter terminal and the second well region floating, the first and second well regions being separated by an impurity region of the first conductivity type such that each of the first and second well regions forms a separate pn junction with the impurity region.

15. The transistor of claim 14 wherein the first and second well regions and the impurity region therebetween are configured such that when the separate pn junctions are reverse biased a boundary of a depletion region in the drift region is substantially flat.

16. The transistor of claim 14 wherein the impurity region has an impurity concentration higher than that of the drift region.

17. The transistor of claim 14 further comprising:
an emitter region of the first conductivity type formed in an upper portion of the first well region, the emitter region being coupled to the emitter terminal; and
a gate terminal extending over but being insulated from a surface area of the first well region between the emitter region and the impurity region.

18. The transistor of claim 14 further comprising a buffer layer between the semiconductor substrate and the drift region and having the same conductivity type as the drift region, the buffer layer having a higher impurity concentration than the impurity region.

19. The transistor of claim 14 wherein a distance between the first well region and the floating well region is in a range of 3 μm to 6 μm.

20. The transistor of claim 14 wherein the thickness of the drift region is in a range of 40 μm to 120 μm.

21. A MOS-gated transistor comprising:
a semiconductor substrate of a first conductivity type, forming a collector region;
a buffer layer of a second conductivity type extending over the semiconductor substrate;
a drift region of the second conductivity type extending over the semiconductor substrate;
a first well region of the first conductivity type formed in an upper portion of the drift region, the first well region being coupled to an emitter terminal;
an impurity region of the second conductivity type formed in an upper portion of the drift region adjacent to the first well region so as to form a first pn junction with the first well region, the impurity region having an impurity concentration higher than that of the drift region but lower than that of the buffer layer;
a floating well region of the second conductivity type formed in an upper portion of the drift region adjacent to the impurity region so as to form a second pn junction with the impurity region, the floating well region being spaced apart from the first well region by the impurity region such that when the first and second pn junctions are reverse biased a boundary of a depletion region in the epitaxial layer is substantially flat;
an emitter region of the first conductivity type formed in an upper portion of the first well region;
a gate insulating layer extending over a surface area of the first well region between the emitter region and the impurity region; and
a gate electrode extending over the gate insulating layer.

22. A method of forming a MOS-gated transistor comprising:
forming a drift region of a first conductivity type over a semiconductor substrate, the semiconductor substrate forming a collector region;
forming a first well region of a second conductivity type in an upper portion of the drift region; the first well region being coupled to an emitter electrode
forming an impurity region of the first conductivity type in an upper portion of the drift region adjacent to the first well region so as to form a pn junction with the first well region, the impurity region having an impurity concentration higher than that of the drift region;
forming a floating well region of the second conductivity type in an upper portion of the drift region adjacent to the impurity region so as to form a pn junction with the impurity region, the floating well region being spaced apart from the first well region by the impurity region;
forming an emitter region in an upper portion of the first well region;
forming a gate insulating layer extending over a surface area of the first well region between the emitter region and the impurity region; and
forming a gate electrode extending over the gate insulating layer.

23. The method of claim 22 further comprising forming a buffer layer over the semiconductor substrate before forming the drift region, the buffer layer having the same conductivity type as the drift region.

24. The method of claim 23 wherein the buffer layer has a higher impurity concentration than the impurity region.

25. The method of claim 22 wherein a distance between the first well region and the floating well region is in a range of 3 μm to 6 μm.

26. The method of claim 22 wherein the thickness of the drift region is in a range of 40 μm to 120 μm.

27. A method of forming a transistor, the method comprising:
forming a drift region of a first conductivity type over a semiconductor substrate, the semiconductor substrate forming a collector region;
forming a first well region of a second conductivity type extending from an upper surface of the drift region into and terminating within the drift region;
forming a second well region of the second conductivity extending from an upper surface of the drift region into and terminating within the drift region, the first well region being coupled to an emitter terminal and the second well region floating; and
forming an impurity region of the first conductivity type in the drift region between the first and second well regions so that each of the first and second well regions forms a separate pn junction with the impurity region.

28. The method of claim 27 wherein the first and second well regions and the impurity region therebetween are formed such that when the separate pn junctions are reverse biased a boundary of a depletion region in the drift region is substantially flat.

29. The method of claim 27 wherein the impurity region has an impurity concentration higher than that of the drift region.

30. The method of claim 27 further comprising:
forming an emitter region of the first conductivity type in an upper portion of the first well region, the emitter region being coupled to the emitter terminal; and
forming a gate terminal extending over but being insulated from a surface area of the first well region between the emitter region and the impurity region.

31. The method of claim 27 further comprising forming a buffer layer over the semiconductor substrate before forming the drift region, the buffer layer having the same conductivity type as the drift region, the buffer layer having a higher impurity concentration than the impurity region.
